(19) United States
(12) Patent Application Publication
(10) Pub. No.: US 2014/0182927 A1
(43) Pub. Date: Jul. 3, 2014

(54) ELECTRONIC DEVICE WITH INDICATING DEVICE

(71) Applicants: HON HAI PRECISION INDUSTRY CO., LTD., New Taipei (TW); HONG FU JIN PRECISION INDUSTRY (WuHan) CO., LTD., Wuhan (CN)

(72) Inventors: BIAO ZENG, Wuhan (CN); ZHI-QIANG LI, Wuhan (CN); YI SHU, Wuhan (CN); CHANG-YONG HU, Wuhan (CN); GUANG-BIN YIN, Wuhan (CN)

(73) Assignees: HON HAI PRECISION INDUSTRY CO., LTD., New Taipei (TW); HONG FU JIN PRECISION INDUSTRY (WUHAN) CO., LTD., Wuhan (CN)

(21) Appl. No.: 14/023,724

(22) Filed: Sep. 11, 2013

(30) Foreign Application Priority Data
Dec. 27, 2012 (CN) 2012105774781

(51) Int. Cl. H05K 7/00

(52) U.S. Cl. CPC H05K 7/005
USPC 174/535

(57) ABSTRACT

An electronic device includes a mounting plate, a front panel, and an identifier film. A mounting bracket is mounted on the mounting plate. An indicating device is secured in the mounting bracket. The front panel is secured on the mounting plate. The front panel defines a light emitting hole aligned with the indicating device. The identifier film is attached on the front panel to cover the light emitting hole. Light emitted by the indicating device emits through an identifier of the identifier film.

### BACKGROUND

1. Technical Field

The present disclosure generally relates to electronic devices, and particularly to an electronic device with an indicating device.

2. Description of Related Art

Indicating devices, such as light-emitting diodes (LEDs), are used to indicate different working states of electronic devices. However, when the indicating devices are mounted on an external surface of the electronic device, the indicating devices can be easily damaged.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an electronic device having indicating devices, according to an exemplary embodiment.

FIG. 2 is similar to FIG. 1, but viewed from another aspect.

FIG. 3 is a partial assembled, isometric view of the electronic device of FIG. 1.

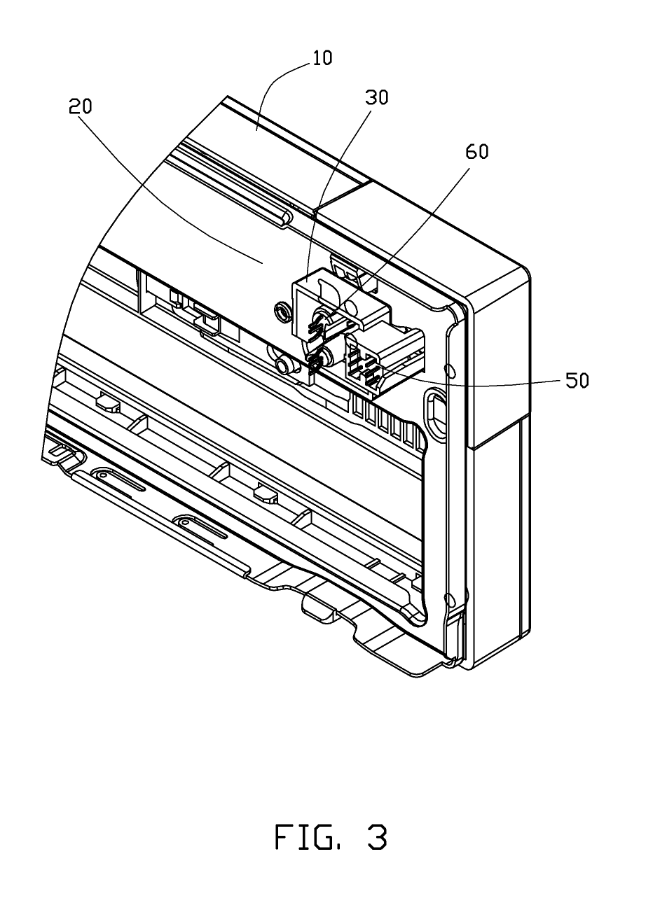

FIG. 4 is similar to FIG. 3, but viewed from another aspect.

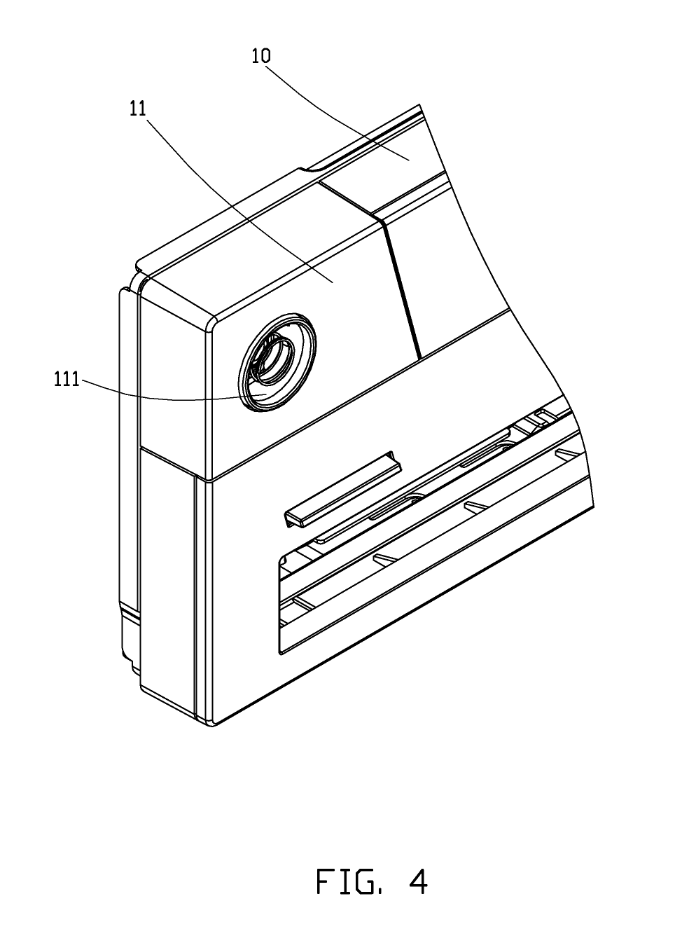

FIG. 5 is similar to FIG. 4, but shows light emitted from the indicating devices.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

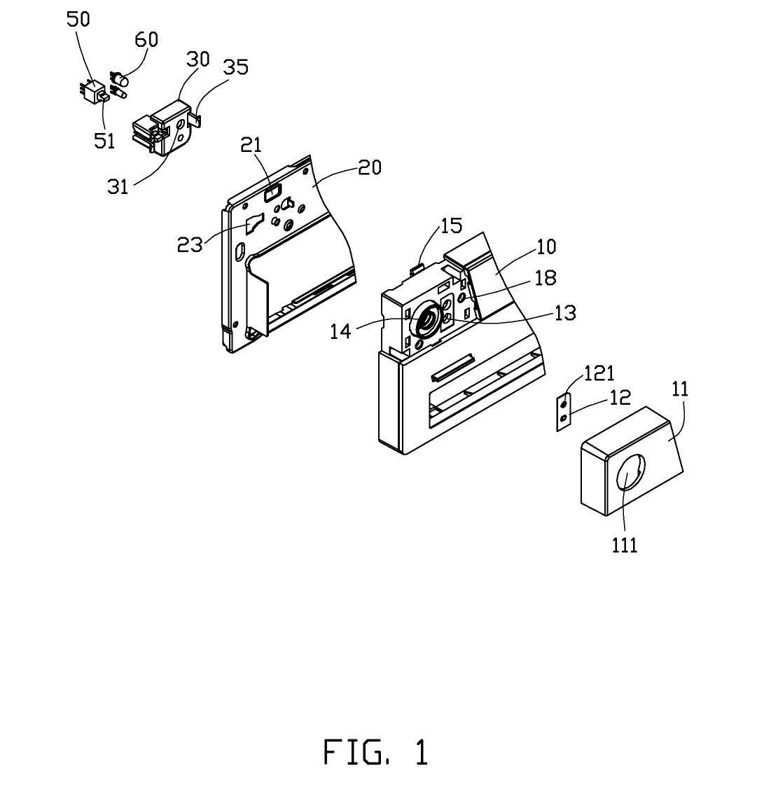

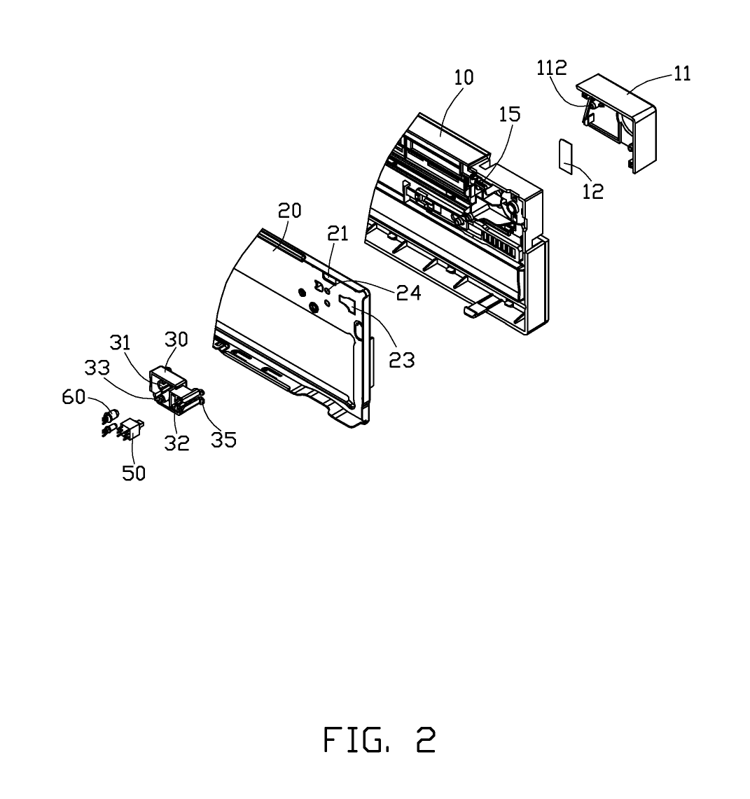

FIGS. 1 and 2 show an embodiment of an electronic device, which includes a front panel 10, a mounting plate 20, a mounting bracket 30, a switch 50, and two indicating devices 60. The indicating devices 60 are LEDs.

The mounting bracket 30 is used to mount the switch 50 and the indicating devices 60 therein. The switch 50 includes a button 51. The mounting bracket 30 defines two receiving holes 31 corresponding to the two indicating devices 60, and defines a receiving slot 32 corresponding to the switch 50. The mounting bracket 30 includes three restricting clips 33. Two restricting clips 33 respectively correspond to the two receiving holes 31, and one restricting clip 33 corresponds to the receiving slot 32. The mounting bracket 30 includes a pair of hooks 35.

The mounting bracket 30 is secured to a rear side of the mounting plate 20. The mounting plate 20 defines engaging holes 23 corresponding to the pair of hooks 35 of the mounting bracket 30. The mounting plate 20 defines two holes 24 corresponding to the two indicating devices 60. The mounting plate 20 also defines an engaging slot 21.

The front panel 10 is secured to a front side of the mounting plate 20. The front panel 10 includes a plurality of clasps 15. The front panel 10 defines a first through hole 14 and two light emitting holes 13. The first through hole 14 corresponds to the switch 50. The two light emitting holes 13 correspond to the two indicating devices 60. The front panel 10 defines a securing hole 18 adjacent to the light emitting holes 13. An identifier film 12 covers the two light emitting holes 13. Two identifiers 121 corresponding to the two indicating devices 60 are located on the identifier film 12. The identifier film 12 is transparent at the two identifiers 121. Therefore, light is transmissible through the two identifiers 121.

The cover 11 is mounted on the front panel 10 to cover the identifier film 12. The cover 11 is semitransparent. The cover 11 defines a second through hole 111 corresponding to the first through hole 14. The cover 11 includes a securing post 112 corresponding to the securing hole 18.

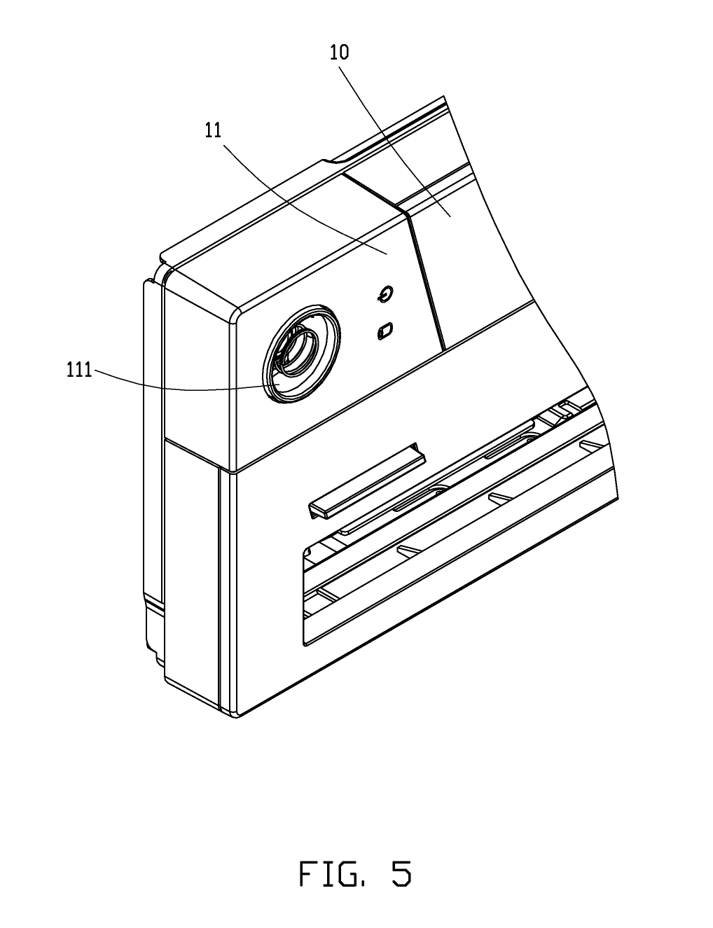

Referring to FIGS. 1 and 5, in assembly, the switch 50 is received in the receiving slot 32. An edge of the switch 50 is clipped by one of the restricting clips 33 to mount the switch 50 in the receiving slot 32. The indicating devices 60 are received in the receiving holes 31. An edge of each indicating device 60 is clipped by a restricting clip 33 to mount the indicating devices 60 in the receiving holes 31. The hooks 35 of the mounting bracket 30 are received in the engaging holes 23 to mount the mounting bracket 30 on the mounting plate 20. A front portion of the indicating devices 60 is received in the holes 24 of the mounting plate 20. The button 51 of the switch 50 is received in the engaging hole 23 of the mounting plate 20.

The clasp 15 of the front panel 10 is received in the engaging slot 21 to mount the front panel 10 on the mounting plate 20, such that the front portions of the indicating devices 60 are received in the light emitting holes 13. The identifier film 12 is attached on the front panel 10, such that the identifiers 121 are aligned with the indicating devices 60. The button 51 of the switch 50 is inserted in the first through hole 14. The securing post 112 of the cover 11 is inserted in the securing hole 18 to mount the cover 11 on the front panel 10. The cover 11 covers the identifier film 12. The button 51 of the switch 50 is inserted in the second through hole 111.

In use, when the switch 50 is flipped, the indicating lights 60 emit light. The light emits through the identifiers 121 and the cover 11 (as shown in FIG. 5). The cover 11 covers the indicating lights 60 from view when the indicating lights 60 do not emit light.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. An electronic device, comprising:
a mounting plate, a mounting bracket mounted on the mounting plate, an indicating device secured in the mounting bracket;
a front panel secured on the mounting plate, the front panel defining a light emitting hole aligned to the indicating device; and
an identifier film attached on the front panel and covering the light emitting hole, an identifier attached to the identifier film, the identifier film being transparent at the identifier, the identifier being aligned to the light emitting hole;
wherein the indicating device emits light transmissible through the identifier and to display the identifier.

2. The electronic device of claim 1, wherein the mounting bracket defines a receiving hole, the indicating device is received in the receiving hole, the mounting bracket comprises a restricting clip located adjacent to the receiving hole, and the indicating device is secured in the receiving hole by engaging the restricting clip on an edge of the indicating device.

3. The electronic device of claim 1, wherein the mounting bracket defines a receiving slot, and a switch is placed in the receiving slot.

4. The electronic device of claim 3, wherein the front panel defines a first through hole, the switch comprises a button, and the button is inserted into the first through hole.

5. The electronic device of claim 1, wherein a semitransparent cover is secured on the front panel to cover the identifier film.

6. The electronic device of claim 5, wherein the semitransparent cover comprises a securing post, the front panel defines a securing hole, and the securing post is inserted into the securing hole.

7. The electronic device of claim 1, wherein the mounting bracket is mounted on a rear side of the mounting plate, and the front panel is mounted on the front side of the mounting plate.

8. The electronic device of claim 7, wherein the mounting bracket defines a hole, and a front portion of the indicating device is inserted into the hole of the mounting plate to be aligned to the light emitting hole.

9. An electronic device, comprising:
a front panel defining a light emitting hole, an indicating device mounted on a rear side of the front panel and aligned to the light emitting hole; and
an identifier film attached on a front side of the front panel and covers the light emitting hole, an identifier attached to the identifier film, the identifier film being transparent at the identifier, the identifier being aligned to the light emitting hole;
wherein the indicating device emits light transmissible through the identifier and to display the identifier.

10. The electronic device of claim 9, wherein a mounting plate is secured to the rear side of the front panel, a mounting bracket is mounted on the mounting plate, and the indicating device is secured in the mounting bracket.

11. The electronic device of claim 10, wherein the mounting bracket defines a receiving hole, the indicating device is received in the receiving hole, the mounting bracket comprises a restricting clip located adjacent to the receiving hole, and the indicating device is secured in the receiving hole by engaging the restricting clip on an edge of the indicating device.

12. The electronic device of claim 11, wherein the mounting bracket defines a receiving slot, and a switch is placed in the receiving slot.

13. The electronic device of claim 12, wherein the front panel defines a first through hole, the switch comprises a button, and the button is inserted into the first through hole.

14. The electronic device of claim 11, wherein the mounting bracket defines a hole, and a front portion of the indicating device is inserted into the hole of the mounting plate to be aligned to the light emitting hole.
